(19) United States
(12) Patent Application Publication
(10) Pub. No.: US 2026/0341657 A1
(43) Pub. Date: Oct. 29, 2026

(54) SYSTEMS AND METHODS FOR PERFORMING PHYSICAL VAPOR DEPOSITION

(71) Applicant: Taiwan Semiconductor Manufacturing Company, Ltd., Hsinchu (TW)

(72) Inventors: Cheng-Yun Lee, Hsinchu City (TW); Kuan-Chia Chen, Hsinchu City (TW); Nai-Hao Yang, Keelung City (TW); Chia-Wei Chen, Hsinchu City (TW); Chin-Fen Lee, Yilan City (TW)

(73) Assignee: Taiwan Semiconductor Manufacturing Company, Ltd., Hsinchu (TW)

(21) Appl. No.: 19/192,529

(22) Filed: Apr. 29, 2025

(51) Int. Cl. H01J 37/34; C23C 14/34; C23C 14/50

(52) U.S. Cl. CPC H01J 37/3441; C23C 14/345; C23C 14/50; H01J 2237/3323

(57) ABSTRACT

Systems and methods are provided for forming coatings on substrates. The systems include a chamber having an enclosure configured to receive and support the substrate and a target material, a gas delivery system configured to direct a gas into the enclosure, and a power supply configured to charge the target material. The system is configured to ionize gas atoms to form a plasma of charged gas ions, accelerate the gas ions toward and collide with the target material to eject atoms therefrom producing charged target material ions, and direct the target material ions through the enclosure to condense on the substrate and thereby form a coating thereon. The system may include a bias-able shield adjacent configured to repel charged ions away from walls of the chamber and/or a bias-able ring configured to attract charged ions towards edges of the substrate.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically represents a cross-sectional view of a first system for performing a physical vapor deposition process on a substrate in accordance with some embodiments;

FIGS. 2 and 3 schematically represent portions of the system of FIG. 1 during operation thereof illustrating aspects of a bias-able shield of the system in accordance with some embodiments;

FIG. 4 schematically represents a cross-sectional view of a second system for performing a physical vapor deposition process on a substrate in accordance with some embodiments;

FIG. 5 schematically represents a portion of the system of FIG. 4 during operation thereof illustrating aspects of a bias-able ring of the system in accordance with some embodiments;

FIG. 6 schematically represents a cross-sectional view of a third system for performing a physical vapor deposition process on a substrate in accordance with some embodiments;

FIG. 7 is a flow chart illustrating a method for performing a physical vapor deposition process on a substrate in accordance with some embodiments; and

FIG. 8 schematically represents an exemplary substrate that was produced using systems and methods in accordance with some embodiments, and images of two locations on the substrate.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the systems. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Direct current (DC) magnetron sputtering is a thin film physical vapor deposition technique used to deposit thin film coatings from electrically conductive target materials onto substrates. It is widely employed in the semiconductor industry for fabricating microchip circuitry.

In DC magnetron sputtering, the target material and the substrate are placed in a vacuum chamber, typically parallel to each other. The chamber is evacuated to a base pressure (e.g., about 0.5 mTorr to 100 mTorr) to remove contaminants such as water vapor and air. After evacuation, the chamber is backfilled with a high-purity inert gas, usually argon, to act as the process gas.

A DC electrical potential (e.g., about −2 to −5 kV) is applied to the target material, making it negatively charged. This voltage ionizes the neutral argon atoms, creating a plasma that consists of positively charged argon ions and free electrons. The positively charged argon ions are accelerated toward the negatively charged target material, where they collide with its surface. These high-energy collisions eject atoms from the target material, that is a process known as sputtering.

The ejected target material atoms travel through the chamber and condense on the substrate, forming a thin film coating. The substrate is typically grounded or held at a negative charge to attract the ejected target material atoms and promote film uniformity.

Magnets positioned behind the target material are used to create a magnetic field that confines the plasma near the surface of the target material. This configuration may enhance the ionization of the process gas, and improve deposition rates. In some systems, the magnets or an array of magnets may be rotated around an outer edge of the target material. However, this arrangement may cause uneven ion distribution due to the rotation mechanism.

Typically, side walls of the chamber are grounded and at least some of the ejected target material atoms contact and are lost on the side walls. This can result changes to the electric field and/or particle distribution within the chamber (e.g., changes to the sheath), a decrease in the ion directionality at edges of the substrate, and/or the occurrence of defects in the thin film coating.

Presented herein are embodiments of systems and methods for direct current (DC) magnetron sputtering for deposition of thin film coatings onto substrates, such as producing layers on semiconductor wafers during a semiconductor fabrication process. In various embodiments, the systems and methods employ electrically bias-able components adjacent to edges of the substate that are configured to repel or attract positively charged target material ions and thereby reduce target material loss and promote uniformity of the thin film coatings.

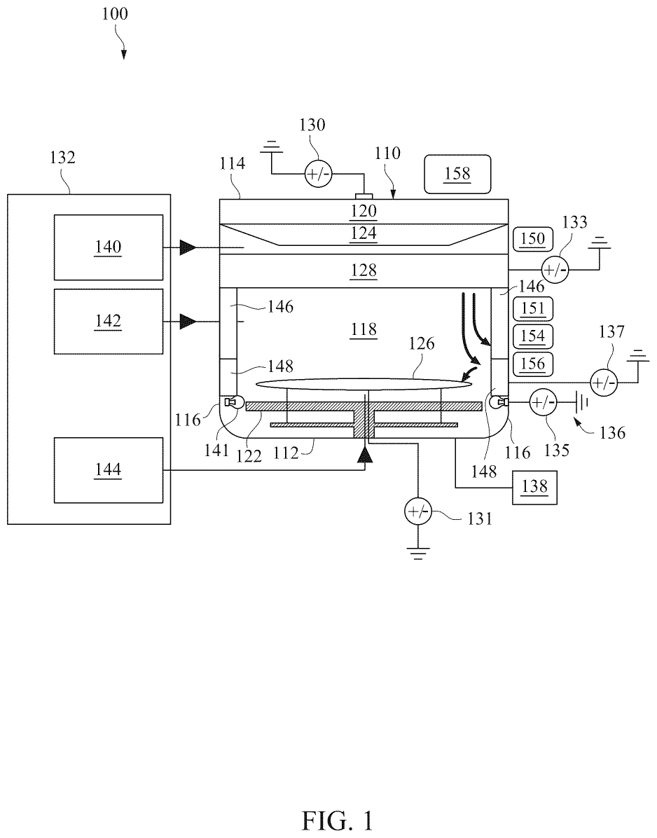

FIG. 1 is a cross-sectional view of a portion of an exemplary DC magnetron sputtering system 100 in accordance with an embodiment. The system 100 includes a chamber 110 having a first wall 112 at a first end thereof (also referred to as the lower end for convenience), a second wall 114 at an opposite, second end thereof (also referred to as the upper end for convenience), and side walls 116 therebetween. The first wall 112, second wall 114, and side walls 116 in combination define an enclosure 118 therebetween within which a DC magnetron sputtering process may be performed. A substrate assembly 122 is disposed adjacent to the first end of the chamber 110 that is configured to releasably support or hold a substrate 126 that is intended to be coated. In some examples, the substrate assembly 122 may include an electrostatic chuck that is configured to generate an electrical force to hold the substrate 126. A target assembly 120 is disposed adjacent to the second end of the chamber 110 that is configured to releasably support or hold a target material 124 that is configured to provide a source material for a thin film coating on the substrate 126.

The system 100 may include a gas supply system 132 that is configured to direct an inert gas (e.g., argon) into the enclosure 118 during operation thereof to function as a process gas. In this example, the system 100 includes three mass flow controllers 140, 142, 144, although the system 100 may include fewer or more mass flow controllers. In various examples, the system 100 may include a vacuum system 138 configured to evacuate the enclosure 118 by applying a suction force thereto to remove contaminates from within the enclosure 118. The system 100 may include a heating system 136 configured to controllably elevate a temperature within the enclosure 118. In some examples, the heating system 136 may include a lamp driver configured to regulate a dc current provided to one or more heat lamps 141 within the enclosure 118 for increasing a temperature of the substrate 126.

In some examples, the system 100 may include a permanent magnet or an array of magnets 158 disposed on a first side of the target assembly 120 opposite to a second side configured to face the substrate assembly 122, that is, on a back side of the target material 124. The permanent magnet or array of magnets 158 may be configured to generate a magnetic field that confines plasma near the surface of the target material 124.

In some examples, the system 100 may include one or more electropermanent magnets disposed along the side wall 116 and configured to adjust or tune ion flux within the enclosure 118. In this example, the system 100 includes a first magnet 150, a second magnet 152, a third magnet 154, and a fourth magnet 156.

In some examples, the system 100 may include a collimator 128 disposed between the substrate 126 and the target material 124 that is configured to restrict and/or direct a flow of atoms ejected from the target material 124 during operation of the system 100 (e.g., only allow positively charged ions to pass therethrough).

The system 100 may include one or more power supply systems that are configured to apply a DC current one or more components and/or devices of the system 100 sufficient for operation thereof or to apply an electrical bias thereto. In some examples, the power supply system 130 is configured to provide power to the gas supply system 132, the vacuum system 138, the array of magnets 158 (e.g., for rotation thereof), and/or the sensors and/or monitoring systems for operation thereof. In FIG. 1, a first power supply system 130 is represented that is configured to apply a DC current to the target material 124 to negatively charge the target material 124, a second power supply system 131 configured to apply a DC current to the substrate 126 to negatively charge the substrate 126, a third power supply system 133 configured to apply a DC current to positively charge the collimator 128, a fourth power supply system 135 configured to provide a DC current to the heating system 136 for operation thereof, and a fifth power supply system 137 configured to apply a DC current to a bias-able shield 148 to positively charge the bias-able shield 148. In some examples, one or more of the first, second, third, fourth, and fifth power supply systems 130, 131, 133, 135, 137 may be part of a single power supply system.

The side walls 116 of the chamber 110 may include at least one chamber shield 146 (also referred to as the non-biased shield 146) configured to cover the side walls 116 and thereby prevent or reduce a likelihood of accumulation of particles on the side walls 116. In some examples, the chamber shield 146 includes a single, integral body having a cylindrical shape, or two or more bodies that in combination define a cylindrical shape. In some examples, the chamber shield 146 covers the side walls 116 from the collimator 128 to a position at or adjacent to the substrate assembly 122 and/or the lower end of the chamber 110. In some examples, the chamber shield 146 may be electrically grounded.

In addition to or as an alternative to the one or more chamber shields 146, the system 100 may include at least one of the bias-able shield 148. In some examples, the bias-able shield 148 is configured to cover the side walls 116 and thereby prevent or reduce a likelihood of accumulation of particles on the side walls 116. In some examples, the bias-able shield 148 includes a single, integral body having a cylindrical shape, or two or more bodies that in combination define a cylindrical shape. In some examples, the bias-able shield 148 covers the side walls 116 from the collimator 128 to a position at or adjacent to the substrate assembly 122 and/or the lower end of the chamber 110. In some examples, the bias-able shield 148 covers the side walls 116 from the chamber shield 146 to a position at or adjacent to the substrate assembly 122 and/or the lower end of the chamber 110. In some examples, a ratio of the heights of the bias-able shield 148 to the chamber shield 146 along the side walls 116 may be about 0.25 to about 0.33. The bias-able shield 148 may receive a voltage from, for example, the fifth power supply system 137 to have a positive charge during operation of the system 100 to repel positively charged ions and thereby reduce the likelihood of contact between the bias-able shield 148 and atoms ejected from the target material 124. This may promote efficiency of the system 100 and/or reduce target material loss during the DC magnetron sputtering process.

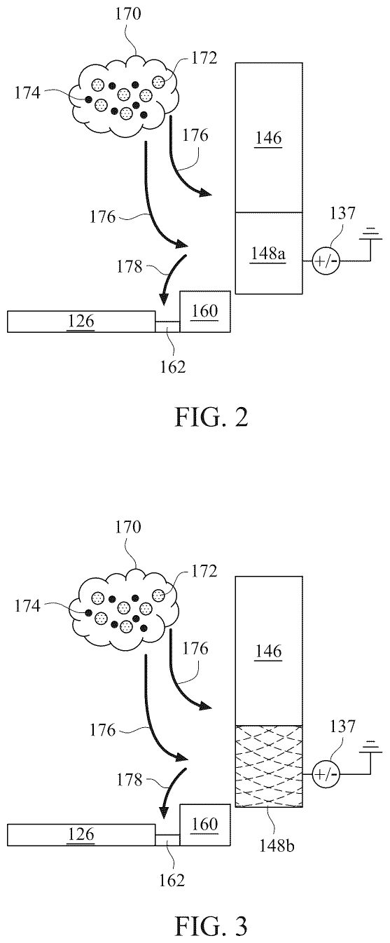

FIGS. 2 and 3 represent enlarged views of a portion of the system 100 adjacent to the bias-able shield 148 and the substrate 126 in accordance with certain embodiments. The represented portion of the system 100 includes a lower edge of the chamber shield 146, the bias-able shield 148, a radially outer edge of the substrate 126, and portions of the substrate assembly 122 including a ring 160 that encircles a perimeter of the substrate 126 and a cover ring 162 between the edge of the substrate 126 and the ring 160.

During the DC magnetron sputtering process, plasma 170 is produced that includes particles such as target material ions 172 and process gas ions 174. Initial directions of flow of the plasma 170 and the particles therein are represented by first arrows 176. As represented, at least some of the particles may be directed toward the chamber shield 146 and/or the bias-able shield 148. However, the bias-able shield 148 may be positively charged to repel the positively charged ions, such as the target material ions 172. The repelling force provided by the bias-able shield 148 may cause the positively charged ions to be redirected to flow toward the substrate 126 as represented with a second arrow 178. This arrangement may reduce particle accumulation on the bias-able shield 148 and/or promote uniform coating of the substrate 126.

The bias-able shield 148 may include or be formed of various materials, such as certain conductive metallic materials (e.g., various aluminum alloys). In some examples, the bias-able shield 148 may be entirely conductive, and in other examples the bias-able shield 148 may include a core body coated with a conductive material. In such examples, the conductive material may be negatively charged by application of a voltage thereto.

The bias-able shield 148 may include various structures and/or surface textures. In the example of FIG. 2, the bias-able shield 148a includes a solid body consisting of a conductive, metallic material having an exposed surface that is substantially flush with an adjacent exposed surface of the chamber shield 146. The thickness of the solid body, the surface texture of the exposed surface of the solid body, the conductivity of the metallic material, and/or other aspects of the solid body may be selected to modify the functionality of the bias-able shield 148. For example, one or more aspects of the solid body, in combination with the specific voltage applied to the solid body, may be chosen to produce a specific repelling force with the bias-able shield 148. In some examples, the system 100 may be configured to allow for selective tuning of a flow direction of the target material ions by adjusting the electrical bias (i.e., the voltage applied thereto) of the bias-able shield 148 and thereby modify the repelling force generated thereby on the target material ions. In such examples, the system 100 or the fifth power supply system 137 may include a controller having one or more processors that are operable or programable to adjust the voltage applied to the bias-able shield 148 and thereby modify ion flux directions.

In the example of FIG. 3, the bias-able shield 148b includes a mesh body consisting of a conductive, metallic material having exposed surfaces that are substantially flush with the adjacent exposed surface of the chamber shield 146. The mesh body may include, for example, a network of woven, welded, or otherwise bonded wires formed of the conductive, metallic material and defining voids or spaces between the wires. The thickness of the mesh body, thicknesses of each of the wires, the sizes and/or shapes of the spaces between the wires, the conductivity of the wires, and/or other aspects of the mesh body may be selected to adjust the functionality of the bias-able shield 148. For example, one or more aspects of the mesh body, in combination with the specific voltage applied to the mesh body, may be chosen to produce a specific repelling force with the bias-able shield 148. In some examples, the mesh body may be configured such that a deposition rate of the thin film coating is improved relative to the solid body example of FIG. 2.

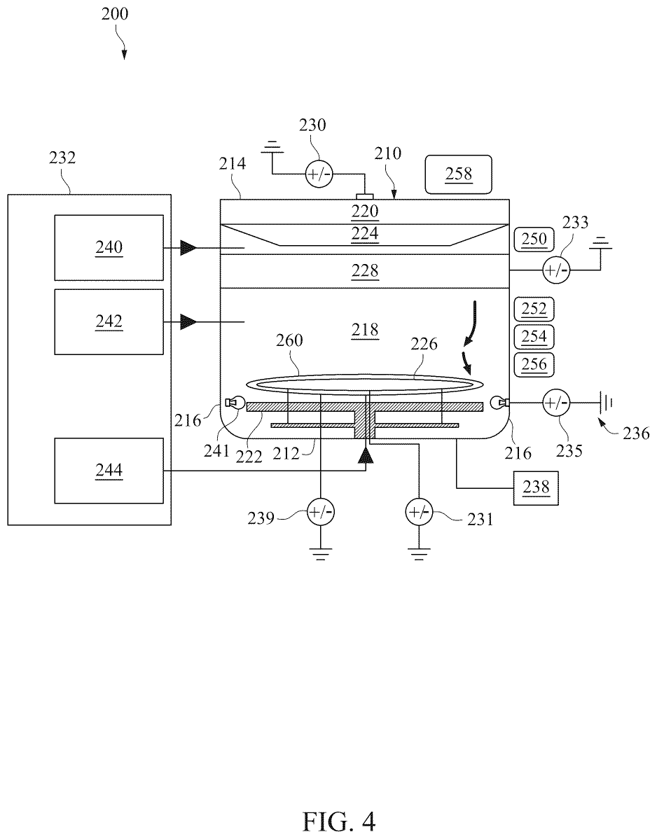

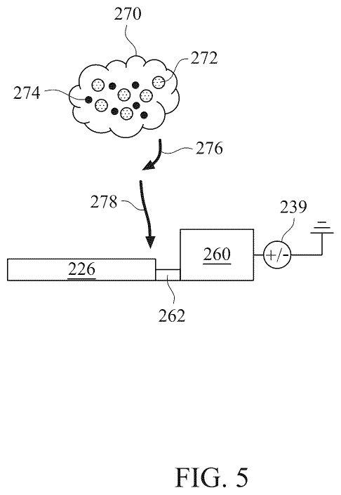

Referring now to FIG. 4, a cross-sectional view of a portion of another exemplary DC magnetron sputtering system 200 is provided in accordance with an embodiment. In view of similarities between the first system 100 and the second system 200, the following discussion of FIGS. 4 and 5 will focus primarily on aspects of the second system 200 that differ from the first system 100 in some notable or significant manner. Other aspects of the second system 200 not discussed in any detail can be, in terms of structure, function, materials, etc., essentially as was described for the first system 100.

The system 200 includes a chamber 210 having a first wall 212 at a first or lower end thereof, a second wall 214 at an opposite, second or upper end thereof, and side walls 216 therebetween which in combination define an enclosure 218. A substrate assembly 222 is disposed adjacent to the first end, and a target assembly 220 is disposed adjacent to the second end. The system 200 may include a gas supply system 232 including three mass flow controllers 240, 242, 244, a vacuum system 238, a heating system 236, and a permanent magnet or an array of magnets 258.

In some examples, the system 200 may include one or more electropermanent magnets disposed along the side wall 216 and configured to adjust or tune ion flux within the enclosure 218. In this example, the system 200 includes a first magnet 250, a second magnet 252, a third magnet 254, and a fourth magnet 256.

The system 200 may include one or more power supply systems that are configured to apply a DC current one or more components and/or devices of the system 200 sufficient for operation thereof or to apply an electrical bias thereto. In various examples, the system 200 may include a collimator 228 disposed between the substrate 226 and the target material 224. In FIG. 4, the system 200 includes a first power supply system 230 configured to bias the target material 224, a second power supply system 231 configured to bias the substrate 226, a third power supply system 233 configured to bias the collimator 228, a fourth power supply system 235 configured to power the heating system 236, and a fifth power supply system 239 configured to apply a DC current to a bias-able ring 260 to negatively charge the bias-able ring 260.

In various examples, the system 200 may include the bias-able ring 260 that encircles a perimeter of the substrate 226. The bias-able ring 260 may receive a voltage from, for example, the fifth power supply system 239 to have a negative charge during operation of the system 200 to attract positively charged ions. In some examples, the bias-able ring 260 may be component of the substrate assembly 222.

FIG. 5 represents an enlarged view of a portion of the system 200 adjacent to a radially outer edge of the substrate 226 in accordance with certain embodiments. The represented portion of the system 200 includes the radially outer edge of the substrate 226, and portions of the substrate assembly 222 including the bias-able ring 260 and a cover ring 262 between the edge of the substrate 226 and the bias-able ring 260.

During the DC magnetron sputtering process, plasma 270 is produced that includes particles such as target material ions 272 and process gas ions 274. As represented, at least some of the particles may be directed toward a central portion of the substrate 226. However, the bias-able ring 260 may be negatively charged to attract the positively charged ions, such as the target material ions 272, and thereby pull the positively charged ions toward an edge portion of the substrate 226. The attraction force provided by the bias-able ring 260 may cause the positively charged ions to be redirected to flow toward edges of the substrate 226 as represented with a first arrow 276 (initial path) and a second arrow 278 (altered path). This arrangement may promote uniform coating of the substrate 226.

The bias-able ring 260 may include or be formed of various materials, such as certain conductive metallic materials. In some examples, the bias-able shield 148 may be entirely conductive, and in other examples the bias-able ring 260 may include a core body coated with a conductive material. In such examples, the conductive material may be negatively charged by application of a voltage thereto.

The bias-able ring 260 may include various structures and/or surface textures. In the example of FIG. 5, the bias-able ring 260 includes a solid body consisting of a conductive, metallic material. The thickness of the solid body, the dimension between the bias-able ring 260 and the edge of the substrate 226, the conductivity of the metallic material, and/or other aspects of the bias-able ring 260 may be selected to modify the functionality of the bias-able ring 260. For example, one or more aspects of the bias-able ring 260, in combination with the specific voltage applied to the bias-able ring 260, may be chosen to produce a specific attraction force with the bias-able ring 260 and/or to tune or adjust a path of flow of the positively charged ions. In some examples, the system 200 may be configured to allow for selective tuning of a flow direction of the target material ions by adjusting the electrical bias (i.e., the voltage applied thereto) of the bias-able ring 260 and thereby modify the attraction force generated thereby on the target material ions. In such examples, the system 200 or the fifth power supply system 239 may include a controller having one or more processors that are operable or programable to adjust the voltage applied to the bias-able ring 260 and thereby modify ion flux directions.

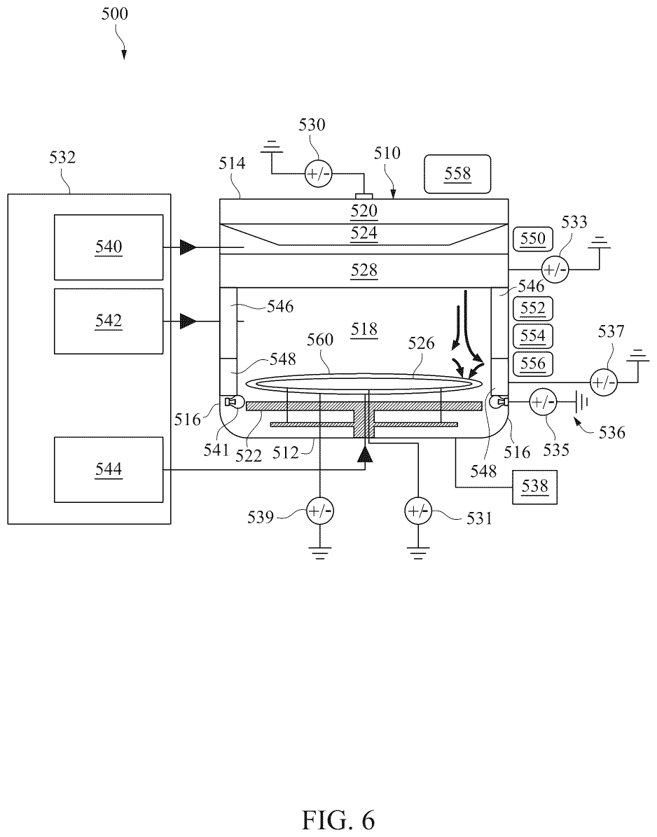

Referring now to FIG. 6, a cross-sectional view of a portion of yet another exemplary DC magnetron sputtering system 500 is provided in accordance with an embodiment. In view of similarities between the first and second systems 100, 200 and the third system 500, the following discussion of FIG. 6 will focus primarily on aspects of the third system 500 that differ from the first and second systems 100, 200 in some notable or significant manner. Other aspects of the third system 500 not discussed in any detail can be, in terms of structure, function, materials, etc., essentially as was described for the first and second systems 100, 200.

The system 500 includes a chamber 510 having a first wall 512 at a first or lower end thereof, a second wall 514 at an opposite, second or upper end thereof, and side walls 516 therebetween which in combination define an enclosure 518. A substrate assembly 522 is disposed adjacent to the first end, and a target assembly 520 is disposed adjacent to the second end. The system 500 may include a gas supply system 532 including three mass flow controllers 540, 542, 544, a vacuum system 538, a heating system 536, an array of magnets 558, electropermanent magnets include a first magnet 550, a second magnet 552, a third magnet 554, and a fourth magnet 556, and a collimator 528.

The system 500 may include one or more power supply systems that are configured to apply a DC current one or more components and/or devices of the system 500 sufficient for operation thereof or to apply an electrical bias thereto. In FIG. 6, the system 500 includes a first power supply system 530 configured to bias the target material 524, a second power supply system 531 configured to bias the substrate 526, a third power supply system 533 configured to bias the collimator 528, a fourth power supply system 535 configured to power the heating system 536, a fifth power supply system 537 configured to apply a DC current to a bias-able shield 548 to positively charge the bias-able shield 548, and a sixth power supply system 539 configured to apply a DC current to a bias-able ring 560 to negatively charge the bias-able ring 560.

The side walls 516 of the chamber 510 may include at least one chamber shield 546 configured to cover the side walls 516 and thereby prevent or reduce a likelihood of accumulation of particles on the side walls 516. In addition to or as an alternative to the one or more chamber shields 546, the system 500 may include the bias-able shield 548. The bias-able shield 548 may receive a voltage from, for example, the fifth power supply system 537 to have a positive charge during operation of the system 500 to repel positively charged ions. In various examples, the system 500 may include the bias-able ring 560 that encircles a perimeter of the substrate 526. The bias-able ring 560 may receive a voltage from, for example, the sixth power supply system 539 to have a negative charge during operation of the system 500 to attract positively charged ions.

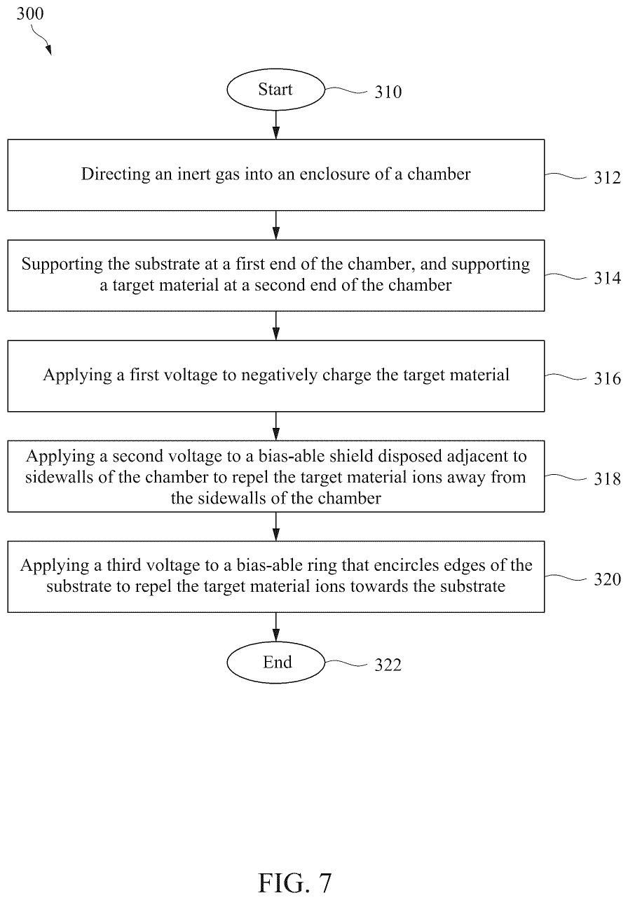

Referring to FIG. 7, an exemplary method 300 is presented for performing physical vapor deposition process on a substrate. In some examples, the physical vapor deposition process may be a DC magnetron sputtering process. In some embodiments, the method 300 may be used to form a thin film coating on the substrate, for example, using one of the systems 100, 200, 500. The method 300 may start at 310. In some examples, the method 300 may include providing a chamber having a first end, a second end, and side walls extending therebetween that in combination define an enclosure. The first end may be configured to receive and support a substrate (e.g., the substrate 126/226/526), for example, with a substrate assembly. The second end may be configured to receive and support a target material (e.g., the target material 124/224/526), for example, with a target assembly. In some examples, the method 300 may include preparing the enclosure of the chamber for the physical vapor deposition process. For example, the method 300 may include evacuating the chamber to a base pressure (e.g., about 0.5 mTorr to 100 mTorr) to remove contaminants such as water vapor and air. In some examples, the temperature of the enclosure may be adjusted (e.g., elevated).

At 312, the method 300 includes directing high-purity inert gas into the enclosure of the chamber to function as a process gas. Various process gases may be used. In some examples, the process gas may be argon.

At 314, the method 300 may include disposing the substrate and the target material within the chamber. In some examples, the method 300 may include supporting the substrate at the first end of the chamber, and supporting a target material at the second end of the chamber. In some examples, the substrate and the target material may be disposed parallel to each other.

The substrate may include various materials. In some examples, the substrate may include a dielectric structure disposed thereon with openings formed therein. In some embodiments, the openings may include a trench and/or a via formed in the dielectric structure. In some embodiments, the dielectric structure may include a single layer. In some alternative embodiments, the dielectric structure may include a multi-layered structure including a plurality of dielectric layers. In some examples, the substrate may be a semiconductor wafer in an intermediate stage of a semiconductor fabrication process. In some examples, the substrate may be one of a variety of types of semiconductor substrates commonly employed in semiconductor integrated circuit fabrication, and integrated circuits may be formed therein and/or thereupon. The semiconductor substrate may be of any construction comprising semiconductor materials, including but not limited to, bulk silicon, a semiconductor wafer, a silicon-on-insulator (SOI) substrate, or a silicon germanium substrate. Other semiconductor materials, including group III, group IV, and/or group V semiconductors, can be used.

The target material may include various materials intended to be deposited as a coating on the substrate. In some examples, the target material may be copper or an alloy thereof.

At 316, the method 300 may include applying a first voltage to negatively charge the target material. In some examples, a DC electrical potential (e.g., about −2 to −5 kV) is applied to the target material. The first voltage applied to the target material may be sufficient, in combination with other parameters of the process, to ionize atoms of the inert gas adjacent to and/or within a proximity of the target material to form a plasma of positively charged gas ions and free electrons. The positively charged gas ions may accelerate toward the negatively charged target material and collide with a surface thereof with sufficient energy to eject atoms from the target material and thereby produce positively charged target material ions. The target material ions may be directed through the enclosure to condense on the substrate and thereby form a thin film coating thereon. In some examples, the method 300 may include directing and/or restricting the flow of the target material ions with a collimator. In some examples, the method 300 may include grounding the substrate or applying a negative potential (e.g., about −700 V) to the substrate to attract the target material ions.

The method 300 may include generating a magnetic field configured to confine the plasma near the surface of the target material with an array of magnets.

At 318, the method 300 may include applying a second voltage to a bias-able shield disposed adjacent to the side walls of the chamber to repel the positively charged ions away from the side walls of the chamber. In some examples, the second voltage may be about −300 to 300 volts (V).

At 320, the method 300 may include applying a third voltage to a bias-able edge ring that encircles edges of the substrate to attract positively charged ions towards edges of the substrate. In some examples, the third voltage may be more negative than the substrate. For example, the substrate may have a charge of about −700 V and the third voltage may be about −750 V or greater (i.e., negative voltage with larger absolute value).

The method 300 may end at 322.

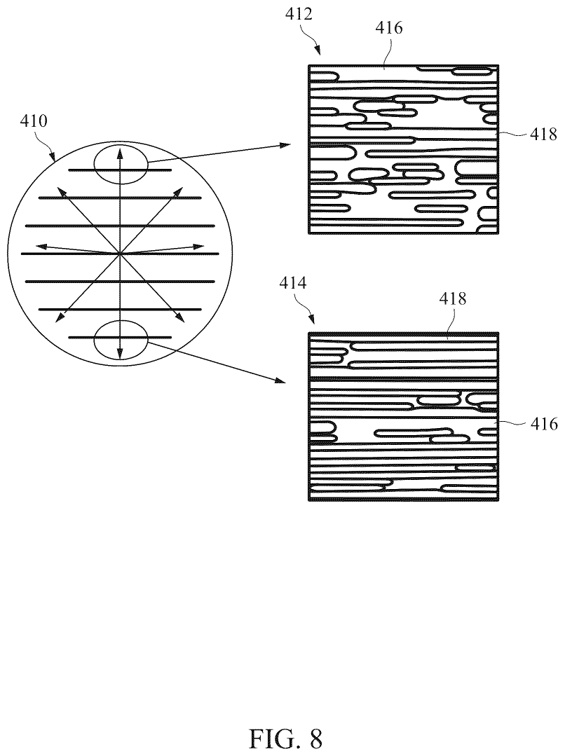

Referring now to FIG. 8, an exemplary substrate 410 is schematically represented that was produced using systems and methods as described herein. Images 412, 414 of two locations on the substrate 410 are shown that include a layer that includes a bulk material 416 and copper lines 418 formed therein (e.g., from a target material). Typically, in semiconductor manufacturing, a layout direction of each layer in, for example, a backend copper process is fixed. In the example of FIG. 8, the layout direction of each layer is represented by horizontal lines. Arrows radiating outward from the center of the substrate 410 represent directions of an electric field, which can correspond to directions of plasma flow. Since the vacuum chambers used in DC magnetron sputtering are centrally symmetric, this outward-radiating electric field will inevitably intersect perpendicularly with the layout of the layers at certain points. In the example of FIG. 8, this intersection occurs at the top and bottom of the substrate 410 (relative to the view represented), which may result in these areas of the substrate 410 being more prone to defects. In certain existing DC magnetron sputtering systems and methods, a typical asymmetry ratio may be about 1.1. During investigations leading to certain aspects of the invention, it was determined that the systems and methods disclosed herein are capable of improving the asymmetry ratio to about 1.5 or greater. For example, in FIG. 8, the copper lines 418 were free of defects that may otherwise occur if produced with certain existing systems or methods.

The present disclosure therefore provides systems and methods for performing physical vapor deposition processes to form thin film coatings on substrates. The systems and methods may include electrically bias-able shields and/or bias-able rings that are configured to repel positively charged ions (e.g., target material ions) away from side walls of a chamber of the systems, towards the substrate, and optionally attract the positively charged ions towards edges of the substrate. These arrangements may reduce target material loss and promote uniform coatings on the substrates. In some examples, these benefits may be achieved while providing deposition rates of equal to or greater than 8.5 A/s, such as equal to or greater than 9.0 A/s.

In accordance with an embodiment, a system is provided for performing physical vapor deposition on a substrate. The system includes a chamber having a first end, a second end, and side walls extending therebetween that in combination define an enclosure. The first end is configured to receive and support the substrate, and the second end is configured to receive and support a target material. The system includes a gas delivery system configured to direct an inert gas into the enclosure of the chamber, a first power supply configured to charge the target material, and a bias-able shield disposed adjacent to the side walls of the chamber configured to be electrically biased to repel charged ions away from the side walls of the chamber. The system is configured to ionize atoms of the inert gas to form a plasma of charged gas ions and free electrons, accelerate the gas ions toward the charged target material and collide with a surface thereof with sufficient energy to eject atoms from the target material producing charged target material ions, and direct the target material ions through the enclosure to condense on the substrate and thereby form a thin film coating thereon.

In accordance with another embodiment, a system is provided for performing physical vapor deposition on a substrate. The system includes a chamber having a first end, a second end, and side walls extending therebetween that in combination define an enclosure. The first end is configured to receive and support the substrate, and the second end is configured to receive and support a target material. The system includes a gas delivery system configured to direct an inert gas into the enclosure of the chamber, a first power supply configured to charge the target material, and a bias-able ring configured to encircle edges of the substrate when received within the enclosure and configured to be electrically biased to attract charged ions towards edges of the substrate. The system is configured to ionize atoms of the inert gas to form a plasma of charged gas ions and free electrons, accelerate the gas ions toward the charged target material and collide with a surface thereof with sufficient energy to eject atoms from the target material producing charged target material ions, and direct the target material ions through the enclosure to condense on the substrate and thereby form a thin film coating thereon.

In accordance with yet another embodiment, a method is provided for performing physical vapor deposition on a substrate. The method includes directing an inert gas into an enclosure of a chamber, supporting the substrate at a first end of the chamber, supporting a target material at a second end of the chamber, and applying a first voltage to charge the target material. Atoms of the inert gas are ionized to form a plasma of charged gas ions and free electrons in response to the charged target material. The gas ions accelerate toward the charged target material and collide with a surface thereof with sufficient energy to eject atoms from the target material producing charged target material ions. The target material ions are directed through the enclosure to condense on the substrate and thereby form a thin film coating thereon. The method includes applying a second voltage to a bias-able shield disposed adjacent to side walls of the chamber to repel the target material ions away from the side walls of the chamber, and applying a third voltage to a bias-able ring that encircles edges of the substrate to attract the target material ions towards edges of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A system for performing physical vapor deposition on a substrate, comprising:
a chamber having a first end, a second end, and side walls extending therebetween that in combination define an enclosure, wherein the first end is configured to receive and support the substrate, wherein the second end is configured to receive and support a target material;
a gas delivery system configured to direct an inert gas into the enclosure of the chamber;
a power supply configured to charge the target material; and
a bias-able shield disposed adjacent to the side walls of the chamber and configured to be electrically biased to repel charged ions away from the side walls of the chamber,
wherein the system is configured to ionize atoms of the inert gas to form a plasma of charged gas ions and free electrons, accelerate the gas ions toward the charged target material and collide with a surface thereof with sufficient energy to eject atoms from the target material producing charged target material ions, and direct the target material ions through the enclosure to condense on the substrate and thereby form a thin film coating thereon.

2. The system of claim 1, wherein the bias-able shield includes a solid body or an assembly of solid bodies that define a cylindrical shape, further comprising a non-biased shield disposed adjacent to the side walls of the chamber, wherein a dimension of the bias-able shield to a non-bias-able shield along the side walls of the chamber is 0.25 to 0.33.

3. The system of claim 1, wherein the bias-able shield includes a mesh body having a network of wires and defined spaces therebetween.

4. The system of claim 1, wherein the bias-able shield is configured to receive a voltage of −300 to 300 V.

5. The system of claim 1, wherein the power supply is configured to negatively chare the target material, the bias-able shield is configured to repel positively charged ions, and the system is configured to form the thin film coating on the substrate at a deposition rate of equal to or greater than 9.0 A/s.

6. The system of claim 1, wherein the system is configured to selectively tune a flow direction of the target material ions by adjusting an electrical bias of the bias-able shield and thereby modify a repelling force generated thereby on the target material ions.

7. A system for performing physical vapor deposition on a substrate, comprising:
a chamber having a first end, a second end, and side walls extending therebetween that in combination define an enclosure, wherein the first end is configured to receive and support the substrate, wherein the second end is configured to receive and support a target material;
a gas delivery system configured to direct an inert gas into the enclosure of the chamber;
a power supply configured to charge the target material; and
a bias-able ring configured to encircle edges of the substrate when received within the enclosure and configured to be electrically biased to attract charged ions towards edges of the substrate,
wherein the system is configured to ionize atoms of the inert gas to form a plasma of charged gas ions and free electrons, accelerate the gas ions toward the charged target material and collide with a surface thereof with sufficient energy to eject atoms from the target material producing charged target material ions, and direct the target material ions through the enclosure to condense on the substrate and thereby form a thin film coating thereon.

8. The system of claim 7, wherein the bias-able ring is configured to receive a voltage that is more negative than a charge of the substrate.

9. The system of claim 7, wherein the power supply is configured to negatively chare the target material, the bias-able shield is configured to repel positively charged ions, and the system is configured to form the thin film coating on the substrate at a deposition rate of equal to or greater than 9.0 A/s.

10. The system of claim 7, wherein the system is configured to selectively tune a flow direction of the target material ions by adjusting an electrical bias of the bias-able ring and thereby modify an attraction force generated thereby on the target material ions.

11. The system of claim 7, further comprising a substrate assembly disposed at or adjacent to the first end of the chamber within the enclosure that is configured to hold the substrate, wherein the bias-able ring is a component of the substrate assembly.

12. The system of claim 11, wherein the substrate assembly includes an electrostatic chuck that is configured to generate an electrical force to hold the substrate.

13. A method for performing physical vapor deposition on a substrate, comprising:
directing an inert gas into an enclosure of a chamber;
supporting the substrate at a first end of the chamber;
supporting a target material at a second end of the chamber;
applying a first voltage to charge the target material, wherein atoms of the inert gas are ionized to form a plasma of charged gas ions and free electrons in response to the charged target material, wherein the gas ions accelerate toward the charged target material and collide with a surface thereof with sufficient energy to eject atoms from the target material producing charged target material ions, wherein the target material ions are directed through the enclosure to condense on the substrate and thereby form a thin film coating thereon;
applying a second voltage to a bias-able shield disposed adjacent to side walls of the chamber to repel the target material ions away from the side walls of the chamber; and
applying a third voltage to a bias-able ring that encircles edges of the substrate to attract the target material ions towards edges of the substrate.

14. The method of claim 13, wherein the side walls of the chamber define a cylindrical shape, and the bias-able shield includes a solid body or an assembly of solid bodies that define a cylindrical shape, wherein applying the second voltage repels the target material ions toward the substrate.

15. The method of claim 13, wherein the bias-able shield includes a mesh body having a network of wires and defined spaces therebetween, wherein the method include forming the thin film coating on the substrate at a deposition rate of equal to or greater than 9.0 A/s.

16. The method of claim 13, wherein the second voltage is 0.1 to 300 V.

17. The method of claim 13, wherein the third voltage is more negative than a charge of the substrate.

18. The method of claim 13, further comprising selectively tuning a flow direction of the target material ions by adjusting an electrical bias of the bias-able shield and thereby modifying a repelling force generated thereby on the target material ions.

19. The method of claim 13, further comprising selectively tuning a flow direction of the target material ions by adjusting an electrical bias of the bias-able ring and thereby modifying an attraction force generated thereby on the target material ions.

20. The method of claim 13, wherein the substrate is a semiconductor wafer and the target material includes copper or an alloy thereof.
